(19) United States
(12) Patent Application Publication
(10) Pub. No.: US 2010/0206378 A1
(43) Pub. Date: Aug. 19, 2010

(54) Thin-film photovoltaic power system with integrated low-profile high-efficiency inverter

(75) Inventors: Robert W. Erickson, JR., Boulder, CO (US); Steven Croft, Menlo Park, CA (US); Shawn Everson, Fremont, CA (US); Aaron Schultz, San Jose, CA (US)

Correspondence Address: FOLEY AND LARDNER LLP;SUITE 500, 3000 K STREET NW, WASHINGTON, DC, 20007, US

(73) Assignee: Miasole

(21) Appl. No.: 12/379,196

(22) Filed: Feb. 13, 2009

(51) Int. Cl. H01L 31/04; H02M 7/00; H02M 1/14

(52) U.S. Cl. 136/259; 363/123; 363/40

(57) ABSTRACT

A photovoltaic device including at least one photovoltaic cell and a transformerless inverter electrically coupled to the at least one photovoltaic cell. The at least one photovoltaic cell and the transformerless inverter are integrated into a photovoltaic package.

### BACKGROUND

The present invention is directed generally to photovoltaic systems and more specifically to photovoltaic systems with an integrated inverter. Development of new technologies for low-cost manufacturing of thin-film photovoltaic (PV) power cells is enabling new types of building materials that integrate photovoltaic power generating elements. In this role, the photovoltaic modules become architectural elements, requiring properties such as a low profile, ease of connection to the utility system, and the ability to maximize energy capture in a complex physical environment having shadows and reflections.

An example is the residential roof shingle, where it is desired that the photovoltaic modules have the appearance of asphalt shingles. To maximize energy capture on a complex multifaceted roof, smart controllers are required that can track PV peak power points on a fine scale. The ability to generate AC simplifies connection to the AC utility system.

### SUMMARY

One embodiment relates to a photovoltaic device including at least one photovoltaic cell and a transformerless inverter. The transformerless inverter can be electrically coupled to the at least one photovoltaic cell. The at least one photovoltaic cell and the transformerless inverter are integrated into a photovoltaic package.

Another embodiment relates to a method of operating a photovoltaic device. An input power can be provided from a photovoltaic cell to a transformerless DC/DC converter. The transformerless DC/DC converter can be operated in at least one of a discontinuous conduction mode or a boundary conduction mode. An output power can be provided from the transformerless DC/DC converter to an unfolder.

Another embodiment relates to a photovoltaic circuit. The photovoltaic circuit includes at least one photovoltaic cell, a storage capacitor, a transformerless DC/DC converter, an electromagnetic interference (EMI) filter, an unfolder, and a controller. The storage capacitor can be electrically coupled to the at least one photovoltaic cell. The transformerless DC/DC converter electrically can be coupled to the storage capacitor. The electromagnetic interference (EMI) filter can be electrically coupled to the transformerless DC/DC converter. The unfolder can be electrically coupled to the EMI filter. The controller can be electrically coupled to the transformerless DC/DC converter.

### BRIEF DESCRIPTION OF THE DRAWINGS

FIG. 1 is a diagram of an photovoltaic power module in accordance with a representative embodiment.

FIG. 2A is a side view of a first photovoltaic package of FIG. 1 in accordance with a representative embodiment.

FIG. 2B is a side view of a second photovoltaic package of FIG. 1 in accordance with a representative embodiment.

FIG. 2C is a side view of a third photovoltaic package of FIG. 1 in accordance with a representative embodiment.

FIG. 2D is a side view of a fourth photovoltaic package of FIG. 1 in accordance with a representative embodiment.

FIG. 3 is a schematic of a circuit of a photovoltaic power module with a buck-type DC/DC converter in accordance with a representative embodiment.

FIG. 4 is a graph of an inductor current waveform plotted for one-half of an AC line period in accordance with a representative embodiment.

FIG. 5 is a close-up view of the graph of the inductor current waveform plotted for one-half of an AC line period of FIG. 4 in accordance with a representative embodiment.

FIG. 6 is a graph of an average inductor current waveform versus a current reference plotted for one-half of an AC line period in accordance with a representative embodiment.

FIG. 7 is a diagram of the controller of the photovoltaic power module of FIG. 3 in accordance with a representative embodiment.

FIG. 8 is a schematic of a circuit of a photovoltaic power module with a buck-boost-type DC/DC converter in accordance with a representative embodiment.

FIG. 9 is a graph of a AC line voltage and energy storage capacitor voltage of a photovoltaic power module with a buck-boost-type DC/DC converter in accordance with a representative embodiment.

### DETAILED DESCRIPTION

A device, method, and circuit of a photovoltaic power module are described. In the following description, for purposes of explanation, numerous specific details are set forth to provide a thorough understanding of exemplary embodiments of the invention. It will be evident, however, to one skilled in the art that the invention may be practiced without these specific details. The drawings are not to scale. In other instances, well-known structures and devices are shown in simplified form to facilitate description of the representative embodiments. Low-power inverters having very low profile and high efficiency are desired. The current state of the art is believed not able to meet these requirements while maintaining a low cost per rated watt, and hence a new inverter approach is needed. It is generally thought impractical to integrate inverters into thin-film PV modules. Rather, current thinking is that the inverter must remain a discrete relatively high-profile element that is either attached to the back of the panel, or is located elsewhere. The aspects of the present invention relate to the integration of low-profile inverters directly into thin-film photovoltaic modules, leading to new architectural building materials for integration of smart photovoltaic power sources into buildings. U.S. patent application Ser. No. ______ (Attorney Docket Number 075122/0147), titled Thin-Film Photovoltaic Power Element With Integrated Low-Profile High-Efficiency DC/DC Converter, filed Feb. 13, 2009 is herein incorporated by reference in its entirety.

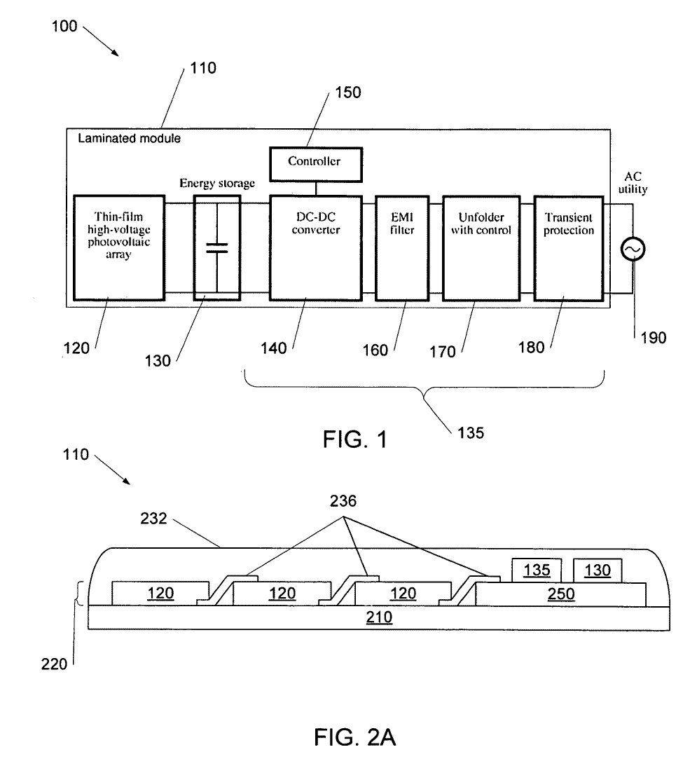

Referring to FIG. 1, a diagram of a photovoltaic power module 100 in accordance with a representative embodiment is shown. The photovoltaic power module 100 is integrated into a photovoltaic package 110. The photovoltaic power module 100 includes an array of photovoltaic cells 120, an energy storage device, such as a capacitor 130 or another storage device, and an inverter 135. The inverter 135 can include a DC/DC converter 140, an electromagnetic interference (EMI) filter 160, an unfolder 170, an optional transient protection 180, and a controller 150. The photovoltaic package 110 can be electrically connected to an AC utility 190 through the transient protection 180. If desired, the transient protection 180 can be part of the AC utility 190 instead of the inverter 135.

The term package includes devices, such as the photovoltaic cells and circuit elements, such as converters and inverters, enclosed between a front barrier and a back barrier. The front barrier is transparent to solar radiation. The front barrier may comprise glass, plastic and/or encapsulant. The back barrier may comprise one or more glass, plastic and/or metal layers in a laminate or a plastic molded back piece. Examples of a package include devices laminated between sheets of plastic or polymer material, such as PET and/or EVA sheets; devices attached to a substrate, where at least some of the devices may be encapsulated in epoxy; and devices sealed between a sheet of glass and a substrate (such as a glass or molded plastic substrate) and/or a sheet of plastic. In a monolithic integration of a package, a single substrate can have multiple cells formed on it. This substrate may or may not be used as part of the structure of the module package. Alternatively, the substrate is omitted and the cells “float” in the encapsulant between the front and back barriers. The encapsulant fills the spaces between the devices and the barrier layers. Alternatively, the space(s) between the barrier layers is filled with air or gas, as in a double paned window.

A package can include multiple layers of different materials. A low profile package preferably has a height less than or equal to 11 mm such as 3 mm-11 mm; for example, 3 mm-6 mm; specifically, 5 mm-6 mm.

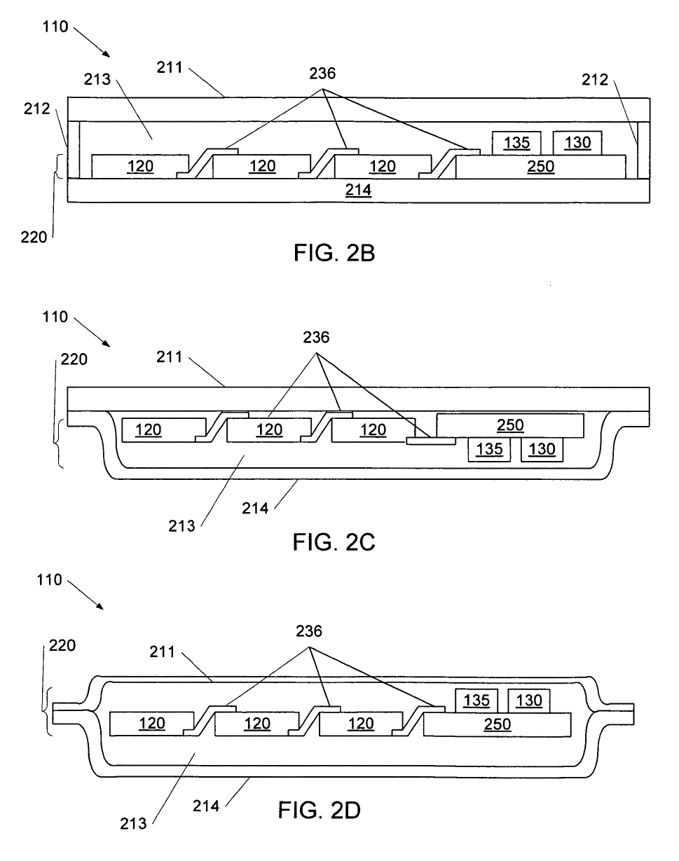

Referring to FIG. 2A-D, side views of various photovoltaic packages of FIG. 1 in accordance with a representative embodiment are shown. The photovoltaic package 110 may comprise a low-profile photovoltaic laminate or non-laminate package. A laminate comprises multiple layers of materials formed together, such as cells 120 and inverter 135 on the substrate encapsulated between two polymer or plastic sheets, as shown in FIG. 2D. The low-profile photovoltaic laminate has a width-to-thickness ratio of about 30:1 to about 200:1 at its smallest width and the height is less than or equal to 11 mm. In other embodiments, the thickness is less than 11 mm; such as 3 mm-11 mm; for example, 3 mm-6 mm; specifically, 5 mm-6 mm. In a representative embodiment, the photovoltaic package 110 is about the size of a typical three-tab residential roofing shingle. Alternatively, the photovoltaic package 110 can be a long sheet such as a roll of photovoltaic roofing material laminated on both sides. The roll of laminated photovoltaic module material can be cut to length. The photovoltaic package 110 can be any low-profile form and in any shape. Alternatively, the photovoltaic package 110 can be a non-laminate type package such as a glass sheet covered package where the electrical components are encapsulated in a polymer encapsulant.

The photovoltaic package 110 comprises a device layer 220 and front and back barrier or encapsulation layers 232 and 210. In a representative embodiment, the substrate (not shown for clarity) of each photovoltaic array 120 is a sheet of metal such as aluminum or galvanized stainless steel; other plastic or glass materials may also be used. The substrate can be rigid or flexible. Photovoltaic arrays 120 can be attached to the substrate using an adhesive such as epoxy Alternatively, the photovoltaic arrays 120 can be formed or printed directly on the substrate such as by sputtering methods shown in U.S. patent application Ser. No. 10/973,714, titled Manufacturing Apparatus And Method For Large-Scale Production Of Thin-Film Solar Cells, filed Oct. 25, 2004 and U.S. patent application Ser. No. 11/451,616, titled Photovoltaic Module With Integrated Current Collection And Interconnection, filed Jun. 13, 2006 which are herein included by reference. The photovoltaic arrays 120 are connected to each other by electrical connections 236. A capacitor 130 and the inverter 135 can be integrated onto a separate substrate, such as a printed circuit board 250, which can then be electrically attached to the photovoltaic arrays 120. Alternatively, the printed circuit board 250 can be a flex circuit. Alternatively, the capacitor and the inverter can be attached, formed or deposited directly onto the barrier layers 232 and 210. The photovoltaic arrays 120 are connected to the printed circuit board 250 by electrical connection(s) 236. The encapsulation layer 232 is formed over the photovoltaic arrays 120 and the printed circuit board 250. The front barrier or encapsulation layer 232 can be a polymer layer, a sheet of glass that is sealed to the photovoltaic arrays 120 or a sheet of polymer or plastic material such as polyethylene terephthalate (PET) or ethylene vinyl acetate (EVA) that is bonded or laminated to the photovoltaic arrays 120 and the other components, such as inverter 135. The back barrier layer 210 is formed under the photovoltaic arrays 120 and the printed circuit board 250, as described with regard to layer 232.

The electrical components such as capacitor 130 and inverter 135 can be surface mounted to the printed circuit board 250 or incorporated into the printed circuit board 250. The electrical and other components can be encapsulated in epoxy and/or encapsulated by the encapsulation layer 232. The printed circuit board 250 can have varying degrees of integration. For example, components such as the capacitors and inductors can be discrete components that are attached to the printed circuit board 250. The main energy storage capacitor 130 can be a ceramic capacitor attached to the printed circuit board 250. Alternatively, the main energy storage capacitor 130 can also be formed into or onto the printed circuit board 250 itself. The various inductors that are part of the inverter can be discrete components. Alternatively, the inductors can also be formed into or onto the printed circuit board 250 itself. For instance, in a multi-level printed circuit board, various trace patterns combined with vias, bond wires, or jump wires can be used to fashion inductors. Alternatively, the printed circuit board 250 can be made of flexible materials and consist of multiple and/or localized layers.

Referring to FIG. 2A, a side view of a first photovoltaic package of FIG. 1 in accordance with a representative embodiment is shown. In this embodiment, the front barrier layer 232 comprises an encapsulant and the rear barrier 210 comprises a molded plastic substrate which supports the cells 120 and the circuit board 250. Referring to FIG. 2B, a side view of a second photovoltaic package of FIG. 1 in accordance with a representative embodiment is shown. The illustrated photovoltaic package 110 comprises a back barrier 214, a device layer 220, and a front barrier 211. In a representative embodiment, the back barrier 214 is a sheet of metal such as aluminum or galvanized stainless steel; other plastic or glass materials may also be used. The back barrier 214 can be rigid or flexible. Photovoltaic arrays 120 can be attached to the back barrier 214 using an adhesive such as epoxy. Alternatively, the photovoltaic arrays 120 can be formed or printed directly on the back barrier 214 as described above. The photovoltaic arrays 120 are connected to each other by electrical connections 236. A capacitor 130 and the inverter 135 can be integrated onto a separate substrate, such as a printed circuit board 250, which can then attached to the back barrier 214. Alternatively, the printed circuit board 250 can be a flex circuit. Alternatively, the capacitor and the inverter can be attached, formed or deposited directly onto the back barrier 214. The photovoltaic arrays 120 are connected to the printed circuit board 250 by electrical connections 236. The front barrier 211 is located over the photovoltaic arrays 120, and the printed circuit board 250. The front barrier 211 can be a sheet of glass. The front barrier 211 is sealed to the back barrier 214 by an edge seal 212. The space between the front barrier 211, the back barrier 214, and the edge seal 212 is filled with an encapsulant 213. Alternatively, the space can be filled with air or a gas such as argon.

Referring to FIG. 2C, a side view of a third photovoltaic package of FIG. 1 in accordance with a representative embodiment is shown. The photovoltaic package 110 comprises a back barrier 214, a device layer 220, and a front barrier 211. In a representative embodiment, the front barrier 211 can be a sheet of glass. Photovoltaic arrays 120 can be attached to the front barrier 211 using an adhesive such as epoxy. Alternatively, the photovoltaic arrays 120 can be formed or printed directly on the front barrier 211 as described above. The photovoltaic arrays 120 are connected to each other by electrical connections 236. A capacitor 130 and the inverter 135 can be integrated onto a separate substrate, such as a printed circuit board 250, which can then attached to the front or back barrier. Alternatively, the printed circuit board 250 can be a flex circuit. Alternatively, the capacitor and the inverter can be attached, formed or deposited directly onto the front barrier 211. The photovoltaic arrays 120 are connected to the printed circuit board 250 by electrical connections 236. The back barrier 214 is sealed against the edges of the front barrier 211. The back barrier 214 is a sheet of plastic, or plastic and metal such as aluminum. The back barrier 214 can be rigid or flexible. The space between the front barrier 211 and the back barrier 214 is filled with an encapsulant 213. Alternatively, the space can be filled with air or a gas such as argon.

Referring to FIG. 2D, a side view of a fourth photovoltaic package of FIG. 1 in accordance with a representative embodiment is shown. The illustrated photovoltaic package 110 comprises a flexible laminate. The photovoltaic package 110 comprises a back barrier 214, a device layer 220, and a front barrier 211. In a representative embodiment, the front barrier 211 and the back barrier 214 can be a sheet or layers of plastic, such as EVA and/or PET. The back barrier 214 can also include a metal such as a metal foil. The photovoltaic arrays 120, capacitor 130, the inverter 135, the printed circuit board 250, and the electrical connections 236 are floating and sealed between the front barrier 211 and the back barrier 214 with an encapsulant 213.

Referring again to FIG. 1, the array of photovoltaic cells 120 can include many series-connected thin-film photovoltaic cells. Each photovoltaic cell produces a low DC voltage, typically a fraction of one volt. A manufacturing technology capable of inexpensively connecting many of these cells in series is employed, such as that described in U.S. patent application Ser. No. 11/451,616, titled Photovoltaic Module With Integrated Current Collection And Interconnection, filed Jun. 13, 2006, so that the array of photovoltaic cells 120 produces a high voltage DC output at its peak power operating point with rated solar irradiation. For example, when the utility voltage is 120 Vrms, and when the DC/DC converter is a buck-type (step-down) converter, this PV output voltage can be in the vicinity of 200 Vdc. The array of photovoltaic cells 120 can include diodes (“backplane or bypass diodes”) that protect the array of photovoltaic cells 120 in the event that the array of photovoltaic cells 120 is partially shadowed, shaded, or has irregular illumination as described in U.S. patent application Ser. No. 11/812,515, titled Photovoltaic Module Utilizing An Integrated Flex Circuit And Incorporating A Bypass Diode, filed Jun. 19, 2007 which is herein included by reference. Each diode is connected in an anti-parallel manner across one or more photovoltaic cells.

The energy storage element, such as a capacitor 130 comprises an energy storage element connected across the terminals of the array of photovoltaic cells 120 (i.e. the capacitor 130 is in series with the array of photovoltaic cells 120). The capacitor 130 keeps the instantaneous power flowing out of the array of photovoltaic cells 120 approximately constant and equal to the maximum power that the array of photovoltaic cells 120 is capable of producing. Since the instantaneous power flowing through a single-phase inverter varies with time, and is zero at those instants when an AC utility voltage passes through zero, the instantaneous power flowing out of the array of photovoltaic cells 120 is not generally equal to the instantaneous power flowing into the inverter 135. Hence, the capacitor 130 maximizes energy capture.

Conventional inverters employ electrolytic capacitors for this purpose; however, electrolytic capacitors do not exhibit the very low profile required for integration into a low-profile module, nor do they meet the requirements of long life and high temperature operation. In a representative embodiment, the capacitor 130 can be a high voltage ceramic chip capacitor. Ceramic chip capacitors exhibit low profiles of less than 11 mm, are capable of high temperature operation, and are relatively inexpensive energy storage elements at rated voltages of greater than 100 V. Ceramic capacitors can be used in the photovoltaic power module 100 because the power levels are so low in the photovoltaic power module 100 that the capacitance required is small. Hence, the total capacitance desired at the applicable voltage rating is available in a ceramic capacitor.

The inverter 135 converts the high voltage DC produced by the array of photovoltaic cells 120 and the capacitor 130 into the AC voltage required for connection to a household electricity systems and/or a utility grid. The inverter 135 is a low-profile and high-efficiency inverter which enables its integration into a thin film module package. The inverter 135 includes a controller for controlling the system voltage and current waveforms. The inverter 135 includes three major blocks: the DC/DC converter 140, the EMI filter 160, and the unfolder 170.

The DC/DC converter 140 includes a transformerless high-voltage DC/DC converter. The term transformerless means that the DC/DC converter power does not flow through a transformer. However, the device may contain a transformer for functions other than power processing, such as to couple a MOSFET gate drive signal between the controller circuit and the MOSFET gate or using a small transformer as current-sensing device to transmit a signal proportional to the transistor or diode current to the controller, etc. The DC/DC converter 140 can be capable of producing an output voltage that is less than or greater than the input voltage. Hence, the DC/DC converter 140 can be a buck converter, a buck converter followed by a boost converter, or a buck-boost converter. As used herein, “buck” and “boost” converters mean any converter that decrease and increase the voltage respectively, and include buck converter circuits, boost converter circuits, SEPIC converter circuits, and Cuk converter circuits. In a representative embodiment, the buck converter, the buck converter followed by the boost converter, or the buck-boost converter are transformerless.

The DC/DC converter 140 can be synchronous or asynchronous. An asynchronous buck converter, for example, can include a transistor, a diode, and an inductor. In asynchronous operation, the transistor switches with a particular duty cycle that results in a lower voltage at the output. A synchronous buck converter, for example, can include two transistors and an inductor (i.e., the diode of the asynchronous converter is replaced by a transistor, such as a MOSFET). In synchronous operation, the two transistors switch alternately with a particular duty cycle that results in a lower voltage at the output; and the controller is modified turn on the additional transistor when the first transistor is off, and optionally also to turn off the additional transistor when the inductor current passes through zero. Likewise, a synchronous or asynchronous boost converter, buck converter followed by a boost converter, or buck- boost converter can be used as part of DC/DC converter 140. Alternatively, in synchronous implementations, a diode can be employed to allow current flow during short delays (dead times). Alternatively, any other device that can produce an output voltage that is less than or greater than the input voltage can be used.

A low-profile severely limits the amount of inductance available for filtering the output of the DC/DC converter 140. Hence, the DC/DC converter 140 includes a high switching frequency and accurate control of its transistor switching to maximize efficiency while producing high quality sinusoidal AC line current waveforms.

To achieve a low profile of several millimeters or less, while also meeting current waveform requirements such as IEEE Standard 1547, DC/DC converter 140 operates with a high switching frequency, typically 100 kHz or more. However, a high switching frequency typically leads to high switching loss, and hence low efficiency. The DC/DC converter 140 employs the discontinuous conduction mode or the boundary conduction mode to avoid these switching losses and achieve high efficiency operation. In discontinuous conduction mode, the inductor current of an inductor of the DC/DC converter goes to zero for at least a period of time before the DC/DC converter cycles or switches. In boundary conduction mode, the inductor current of an inductor of the DC/DC converter goes to zero for an instant before the DC/DC converter cycles or switches.

The EMI filter 160 separates the high-frequency switching elements of the DC/DC converter 140 and the unfolder 170. Meeting regulatory limits on conducted EMI, such as those imposed by FCC Part 15 Subpart B, requires that a filter be placed between the high-frequency switching elements and the AC utility. Conventional inverters employ AC EMI filters for this purpose, which typically include high-profile AC-rated capacitors. The EMI filter 160 employs a DC EMI filter that uses low-profile DC-rated capacitors. This is achieved by positioning the EMI filter 160 on the DC side of the unfolder 170, and by avoiding high-frequency switching of unfolder elements. The DC side of the unfolder 170 is the power input of the unfolder 170. The AC side of the unfolder 170 is the power output of the unfolder 170. Hence, bulky and expensive ac-rated capacitors are largely avoided thereby reducing the height of the inverter circuitry. Alternatively, the EMI filter 160 can be located on the AC side of the unfolder 170. Alternatively, the EMI filter 160 can be distributed throughout the inverter 135.

The unfolder 170 is a slow inverter, whose transistors switch at the zero crossings of the AC line voltage waveform. In a representative embodiment, discussed further below, the unfolder includes a diode and four bipolar junction transistors. When the AC line voltage of the AC utility 190 is positive, the controller 150 turns on two transistors, and turns off two transistors. When the AC line voltage of the AC utility 190 is negative, the controller 150 reverses the states of the transistors thereby creating alternating current from direct current. The diode protects the DC-side elements of the system from utility voltage transients, and prevents inrush currents.

The optional transient protection 180 can be included on the AC side of the unfolder 170. When integrated into the photovoltaic power module 100, the transient protection 180 includes a small low-profile transient protector. The photovoltaic power module 100 can be electrically connected to an AC utility 190 through the transient protection 180. Alternatively, the system transient protection 180 can be located in a central box where photovoltaic power modules are tied to the utility grid, instead of or in addition to the transient protection 180 of the photovoltaic power module 100.

The photovoltaic power module 100 is controlled by a controller 150. The controller 150 provides the duty cycle modulation and/or frequency modulation, required to maintain operation in the discontinuous or boundary conduction modes, while synthesizing the required AC line current waveform. The controller 150 performs additional required functions including peak power tracking, anti-islanding, etc. as described in more detail below. In a representative embodiment, some or all of the control functions are realized through the use of digital circuitry, enabling a greater degree of sophistication. The controller 150 can be a central, integrated controller or, alternatively, individual sections of the photovoltaic power module 100 can have dedicated controllers. For example, the DC/DC converter 140 and the unfolder 170 can have separate controllers. Optionally, the controller 150 can use voltage, current or other information from the array of photovoltaic cells 120, the energy storage device 130, the DC/DC converter 140, the electromagnetic interference (EMI) filter 160, the unfolder 170, the optional transient protection 180, and the AC utility 190.

When the a plurality of photovoltaic power modules are combined together, the resulting system of “smart PV modules” is able to adapt to a changing environment, maximizing energy capture in the presence of complex shadows and reflections. With the addition of communications capability, it is further possible to obtain operational and performance data on a fine scale.

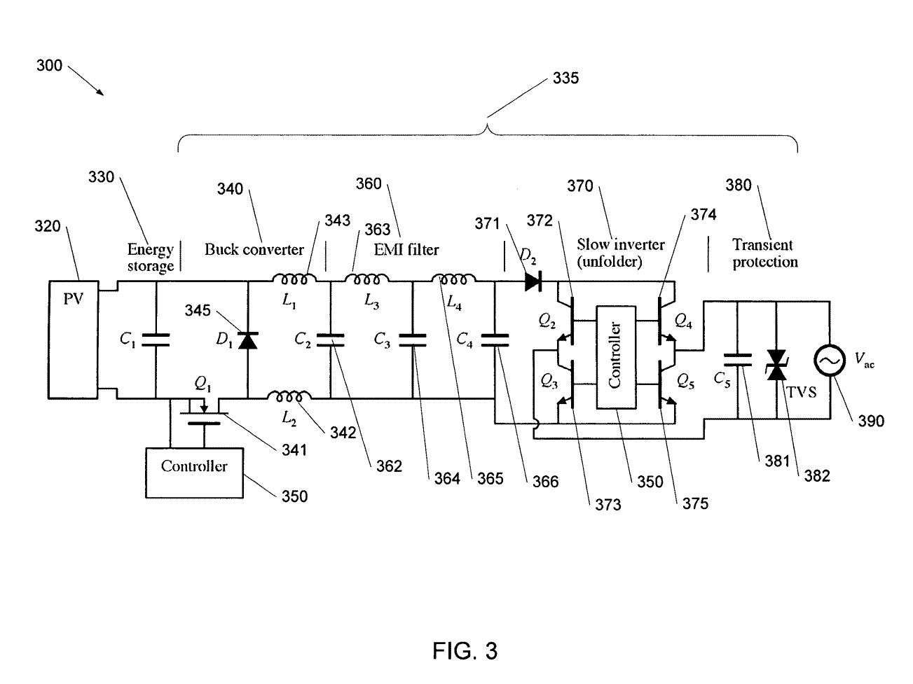

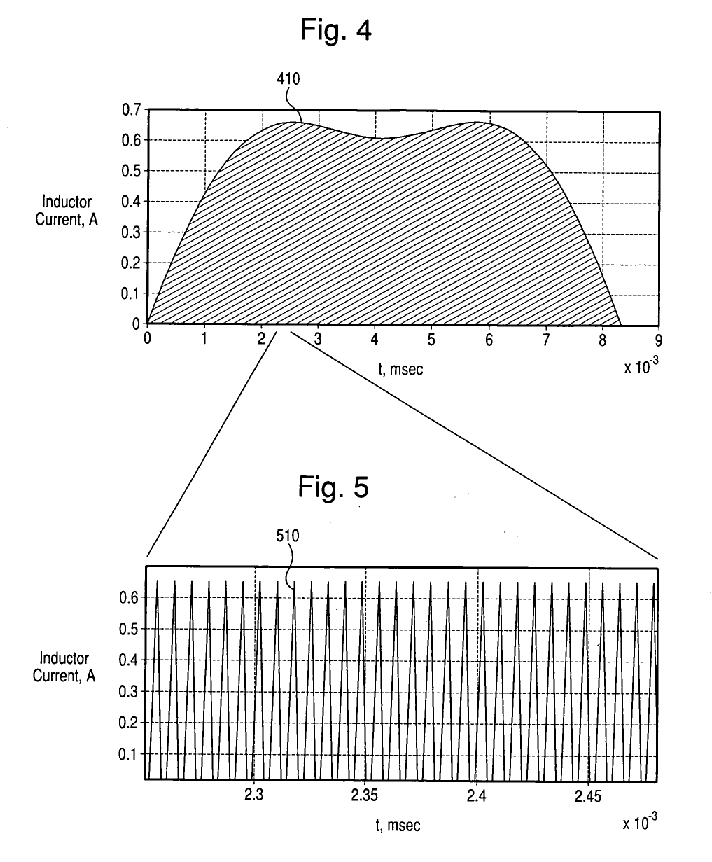

Referring to FIG. 3, a schematic of a circuit of a photovoltaic power module 300 with a buck-type DC/DC converter in accordance with a representative embodiment is shown. The photovoltaic power module 300 includes an array of photovoltaic cells 320, a capacitor 330, and an inverter 335. The inverter 335 can include a DC/DC converter 340, an electromagnetic interference (EMI) filter 360, an unfolder 370, transient protection 380, and a controller 350. The controller 350 controls DC/DC converter 340 and unfolder 370. The controller 350 is also electrically connected to the array of photovoltaic cells 320, the capacitor 330, the EMI filter 360, the transient protection 380, and the AC utility 390. The photovoltaic power module 300 can be electrically connected to an AC utility 390 through the transient protection 380.

The DC/DC converter 340 is a buck converter. The buck converter includes a diode 345 (D1), a transistor 341 (Q1), an inductor 342 (L2), and an inductor 343 (L1). The EMI filter 360 includes a capacitor 362 (C2), an inductor 363 (L3), a capacitor 364 (C3), an inductor 345 (L4), and a capacitor 366 (C4).

The unfolder 370 is a slow inverter, whose transistors switch at the zero crossings of the AC line voltage waveform. In a representative embodiment, the unfolder 370 includes diode 371 (D2) and bipolar junction transistors 372-375 (Q2 through Q5). When the AC line voltage v_{ac}(t) is positive, the controller 350 turns on transistors 373 (Q3) and 374 (Q4), and turns off transistors 372 (Q2) and 375 (Q5). When vac(t) is negative, the driver turns on transistors 372 (Q2) and 375 (Q5), and it turns off transistors 373 (Q3) and 374 (Q4). Diode 371 (D2) protects the DC-side elements of the system from utility voltage transients, and prevents inrush currents. The transient protection 380 includes a capacitor 381 (C5) and a transient voltage suppressor 382.

Two ways to achieve high efficiency with a small inductance in photovoltaic power module 300 are to operate the DC/DC converter 340 in the discontinuous conduction mode (DCM) or in the boundary conduction mode (BCM). In standard operation, a DC/DC converter is switched at a constant frequency. Consequently, the inductor current of an inductor of the DC/DC converter may not go to zero before the DC/DC converter cycles or switches, resulting in power loss. An example of the discontinuous conduction mode is described. In DCM, the switching period of the transformerless buck converter ends sometime after the inductor current of either inductor 342 (L2) or inductor 343 (L1) reaches zero. Referring to FIG. 4, a graph of an inductor current waveform plotted for one-half of an AC line period in accordance with a representative embodiment is shown. A simulated inductor current waveform 410 for DCM operation shows the instantaneous inductor current waveform of inductor 342 (L2) of FIG. 3 for one half of a 60 Hz AC line period (i.e. for 8.33 milliseconds). Referring to FIG. 5, a close-up view of the graph of the inductor current waveform plotted for one-half of an AC line period of FIG. 4 in accordance with a representative embodiment is shown. A simulated inductor current waveform 510 for DCM operation shows the instantaneous inductor current waveform of an DC/DC converter inductor for a 250 microsecond portion of the waveform of FIG. 4.

Referring again to FIG. 3, in a DCM example related to FIGS. 4 and 5, transistor 341 (Q1) is turned on and off at a constant switching frequency of approximately 130 kHz, and its duty cycle is varied by the controller 350 as necessary to produce a high quality nearly sinusoidal utility current waveform. While transistor 341 (Q1) is on, a positive voltage is applied to an inductor 342, causing the inductor current to increase. When transistor 341 (Q1) is turned off, the positive inductor current forward-biases diode 345 (D1). A negative voltage is then applied across the inductor 342, and the inductor current decreases. In the discontinuous conduction mode, the inductor current reaches zero before the end of the switching period. Diode 345 (D1) then becomes reverse-biased, and the inductor current is zero for the remainder of the switching period. Because the diode 345 (D1) is reverse-biased when transistor 341 (Q1) next switches on, the switching loss associated with the diode reverse-recovery process is largely avoided. This switching loss can be the largest single source of power loss in the thin-film integrated inverter, and hence its avoidance through DCM operation can lead to a high-efficiency design.

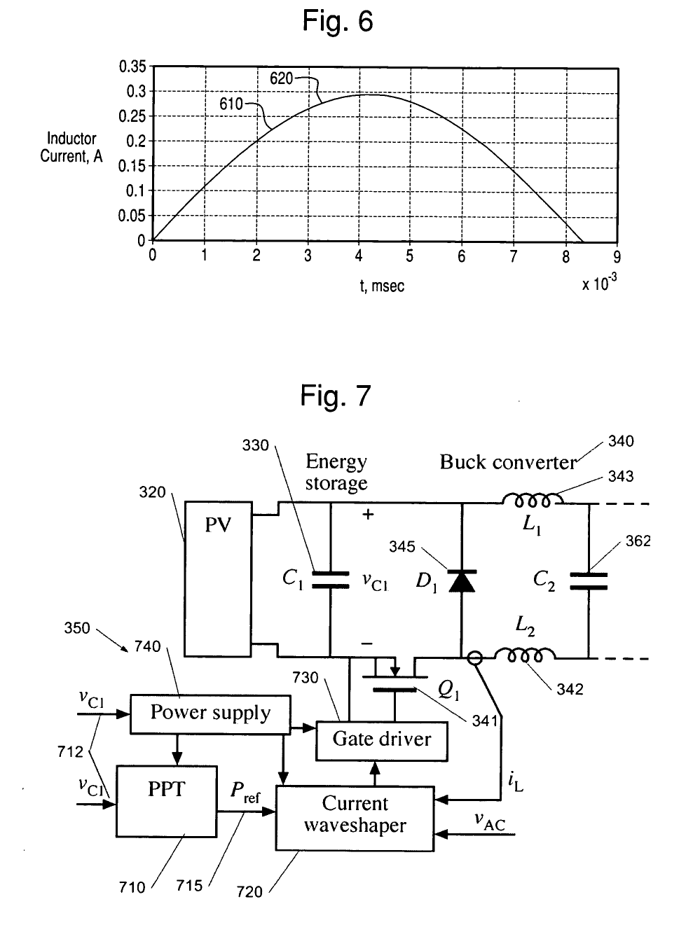

Referring to FIG. 6, a graph of an average inductor current waveform 610 versus a current reference 620 plotted for one-half of an AC line period in accordance with a representative embodiment is shown. The average inductor current waveform 610 is the average, or low-frequency component, of the instantaneous inductor current 410 of FIG. 4. For reference, the current reference 620 is also plotted. The current reference 620 is sinusoidal waveform that represents a 120 Vrms AC utility. The two waveforms are nearly identical.

Referring again to FIG. 3, as described further below, the controller 350 varies the transistor 341 (Q1) duty cycle as necessary to achieve a sinusoidal average current waveform. This in turn leads to a sinusoidal utility current waveform i_{ac}(t). Of course, in practice this current waveform will not be perfectly sinusoidal, but will be sufficiently close to sinusoidal to meet the limits specified in applicable standards such as IEEE 1547.

In the boundary conduction mode (BCM), the controller 350 turns on transistor 341 (Q1) to initiate the next switching period immediately after the inductor current reaches zero, whereas in DCM the inductor current goes to zero for at least a period of time. Operation in this mode also essentially eliminates the switching loss induced by the diode reverse recovery process, and hence it can also exhibit high efficiency in the thin-film inverter application. The switching frequency can vary significantly in this mode. In BCM, the switching period of the transformerless buck converter ends when the inductor current of either inductor 342 (L2) or inductor 343 (L1) reaches zero.

The controller 350 of the DC/DC converter switches transistor 341 (Q1) on and off to simultaneously perform the following functions: maximizing the average power produced by the photovoltaic array, producing a sinusoidal utility current waveform i_{ac}(t), and minimizing switching loss by ensuring that the inductor current is zero at the times that transistor 341 (Q1) turns on. Digital control circuitry may be employed to realize these functions. For example, the sinusoidal utility current waveform can be controlled using digital current-mode control algorithms. The power of the array of photovoltaic cells 320 can be maximized using one of the well-known peak-power-tracking algorithms such as the “perturb and observe” method. To ensure that the inductor current is zero at the time when transistor 341 (Q1) turns on, the controller 350 senses a signal indicative of this (the inductor current, diode current, or the voltage at the node where transistor 341 (Q1) and diode 345 (D1) are interconnected) just before transistor 341 (Q1) is to be turned on. If this signal indicates that the inductor current is not zero, then the controller 350 takes one of the following steps: reduce the switching frequency, or reduce the current reference.

Referring to FIG. 7, a diagram of the controller 350 of the photovoltaic power module of FIG. 3 in accordance with a representative embodiment is shown. The control system 700 includes a peak power tracker (PPT) controller 710, a current waveshaper controller 720, a gate driver 730, and a power supply 740. The controller 350 controls a DC/DC converter 340 which includes a diode 345 (D1), a transistor 341 (Q1), an inductor 342 (L2), and an inductor 343 (L1) as discussed above. The controller 350 is also electrically connected to an array of photovoltaic cells 320, a capacitor 330, an EMI filter, transient protection, an unfolder, and an AC utility. The EMI filter includes a capacitor 362 (C2).

The peak power tracker (PPT) controller 710 adjusts a power reference signal 715 (Pref) sent to a current waveshaper controller 720, such that the power supplied by the array of photovoltaic cells 320 is maximized. The power reference signal 715 (P_{ref}) is updated about once per half-cycle of the AC utility voltage. The PPT controller 710 employs information on a capacitor voltage 712 (v_{C1}) of capacitor 330. The PPT controller 710 can also use the inverter current, to update the power reference signal 715 (P_{ref}).

The current waveshaper controller 720 controls the wave shape of the output of the inverter. The current waveshaper controller 720 generates a logic signal that commands transistor 341 (Q1) to switch on and off. The current waveshaper controller 720 can alter the duty cycle of the switching period of transistor 341 (Q1) in order to shape the output of the unfolder. For example, in discontinuous conduction mode, a digital current-mode controller can make the average inductor current track a reference current signal i_{ref} by implementation of the following control law:

$$d ( {nT}_{s} ) = \frac{d ( ( n - 1 ) {T}_{s} ) + k ( {i}_{ref} ( {nT}_{s} ) + \frac{{i}_{1}^{2} ( {nT}_{s} )}{{m}_{2} ( {nT}_{s} ) {T}_{s}} )}{1 + {ki}_{L} ( {nT}_{s} ) ( 1 - \frac{{m}_{1} ( {nT}_{s} )}{2 {m}_{2} ( {nT}_{s} )} )}$$

In this equation, k is a controller gain, Tₛ is the switching period, d is the transistor duty cycle, n is an integer, i_{L} is the value of the inductor current sampled in the middle of the transistor conduction interval. The quantities m₁ and m₂ are the slopes of the inductor current waveform during the transistor conduction interval and the diode conduction interval, respectively. For the buck DC/DC converter, these are given by m1=(v_{C1}−|v_{ac}|)/L and m₂=−|v_{ac}|/L. Other control laws are possible as well. In one example, a current-mode controller can generate the reference signal i_{ref} by generating a positive half-wave sinusoidal reference whose zero-crossings coincide with the zero crossings of the AC utility line voltage, and whose amplitude is proportional to the power reference signal P_{ref}. A feedback loop inside the current waveshaper controller 720 adjusts the transistor duty cycle as necessary to cause the inverter output current to be proportional to reference signal i_{ref}. In addition, the current waveshaper controller 720 ensures that the inductor current is zero at the time when transistor 341 (Q1) turns on, as described above.

In another representative embodiment, the low-profile inductors and energy storage capacitor can be further reduced in size by using a DC/DC converter having buck-boost (voltage step-up and step-down) capability, and with a modified controller algorithm. Buck-boost capability leads to three significant benefits. First, the inverter becomes capable of operating with a larger energy-storage-capacitor voltage ripple. Hence, the size of the energy storage capacitor can be reduced. Second, the inverter can be designed to operate with a DC input voltage that is slightly lower than the peak AC line voltage. This allows reduction in the size of the low-profile inductor. Third, the added boost capability enables the inverter to continue to function when its PV source is partially shaded, thereby further improving energy capture.

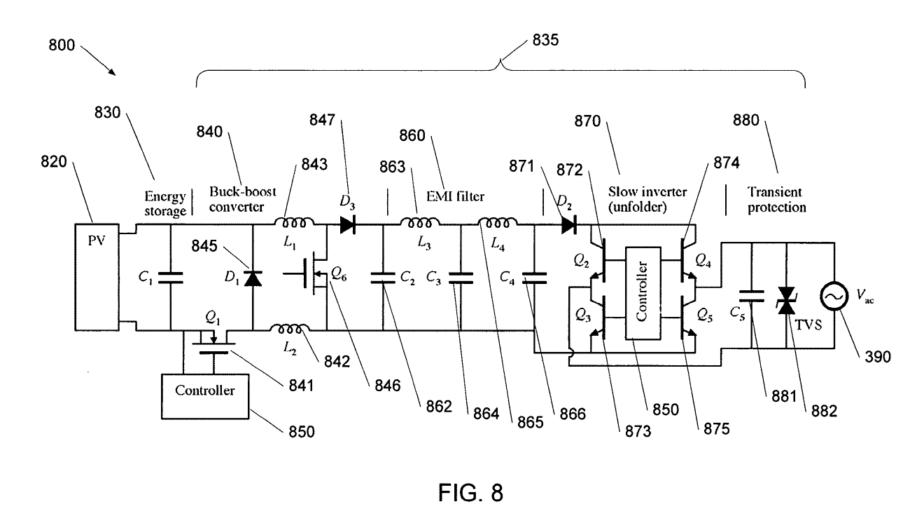

Referring to FIG. 8, a schematic of a circuit of a photovoltaic power module with a buck-boost-type DC/DC converter in accordance with a representative embodiment is shown. The photovoltaic power module 800 includes an array of photovoltaic cells 820, a capacitor 830, and an inverter 835. The inverter 835 can include a DC/DC converter 840, an electromagnetic interference (EMI) filter 860, an unfolder 870, transient protection 880, and a controller 850. The controller 850 controls DC/DC converter 840 and unfolder 870. The controller 850 is also electrically connected to the array of photovoltaic cells 820, the capacitor 830, the EMI filter 860, the transient protection 880, and the AC utility 890. The photovoltaic power module 800 can be electrically connected to an AC utility 890 through the transient protection 880.

The DC/DC converter 840 is a buck-boost converter. The buck converter includes a diode 845 (D1), a transistor 841 (Q1), an inductor 842 (L2), an inductor 843 (L1), a second transistor 846 (Q6), and a second diode 847 (D3). The EMI filter 860 includes a capacitor 862 (C2), an inductor 863 (L3), a capacitor 864 (C3), an inductor 865 (L4), and a capacitor 866 (C4).

The unfolder 870 is a slow inverter, whose transistors switch at the zero crossings of the AC line voltage waveform. In a representative embodiment, the unfolder 870 includes diode 871 (D2) and bipolar junction transistors 872-875 (Q2 through Q5). When the AC line voltage vac(t) is positive, the controller 850 turns on transistors 873 (Q3) and 874 (Q4), and turns off transistors 872 (Q2) and 875 (Q5). When vac(t) is negative, the driver turns on transistors 872 (Q2) and 875 (Q5), and it turns off transistors 873 (Q3) and 874 (Q4). Diode 871 (D2) protects the DC-side elements of the system from utility voltage transients, and prevents inrush currents. The transient protection 880 includes a capacitor 881 (C5) and a transient voltage suppressor 882.

With respect to the buck type embodiment described above with respect to FIG. 3, the second transistor 846 (Q6) and second diode 847 (D3) have been added. The controller 850 also drives the second transistor 846 (Q6). When the voltage of the capacitor 830 is greater than the voltage on the DC side of the unfolder 870 (buck mode), the controller 350 varies the duty cycle of the transistor 841 (Q1) while maintaining the second transistor 846 (Q6) in the off state. When the voltage of the capacitor 830 is less than the voltage on the DC side of the unfolder 870 (boost mode), the controller 850 varies the duty cycle of the second transistor 846 (Q6) while maintaining the transistor 841 (Q1) in the on state (boost mode). Since the voltage of the capacitor 830 is closer to the voltage on the DC side of the unfolder 870, less voltage is applied across inductor 842 (L2) and inductor 843 (L1), and hence their inductances can be reduced. Boost capability also allows the inverter 835 to continue to operate when the voltage of the capacitor 830 is lower than the peak AC utility voltage. As noted previously, this allows reduction of the size and cost of the capacitor 830, and it also allows the inverter 835 to capture energy when the array of photovoltaic cells 820 is partially shaded and produces reduced voltage.

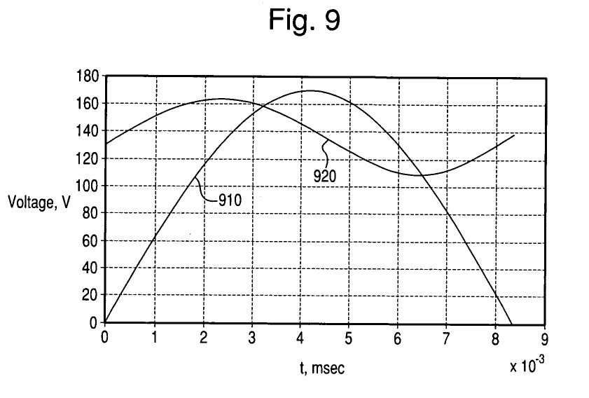

Referring to FIG. 9, a graph of a AC line voltage and energy storage capacitor voltage of a photovoltaic power module with a buck-boost-type DC/DC converter in accordance with a representative embodiment is shown. An energy storage capacitor voltage 920 is shown with respect to an AC line voltage 910 of a buck-boost type circuit. The sinusoidal form of the AC line voltage 910 shows that the buck-boost inverter is capable of operating with a large energy-storage-capacitor voltage ripple and that the DC input voltage that is slightly lower than the peak AC line voltage where the energy storage capacitor voltage 920 is the input to the buck-boost converter.

The foregoing description of the exemplary embodiments have been presented for purposes of illustration and of description. It is not intended to be exhaustive or to limit the invention to the precise form disclosed, and modifications and variations are possible in light of the above teachings or may be acquired from practice of the invention. For example, the described exemplary embodiments focused on an representative implementation of a buck and a buck-boost converter for implementation on a 120V AC utility grid. The present invention, however, is not limited to a representative implementation as described and depicted. Those skilled in the art will recognize that the device and methods of the present invention may be practiced using various combinations of components. Additionally, the device and method may be adapted for different utility grid standards. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

What is claimed is:

1. A photovoltaic device, comprising:
at least one photovoltaic cell; and
a transformerless inverter electrically coupled to the at least one photovoltaic cell,
wherein the at least one photovoltaic cell and the transformerless inverter are integrated into a photovoltaic package.

2. The device of claim 1, wherein the photovoltaic package comprises a low-profile laminate or non-laminate package.

3. The device of claim 2, wherein the low-profile package is less than 11 mm thick.

4. The device of claim 3, wherein the low-profile package is less than 5 mm thick.

5. The device of claim 2, wherein the at least one photovoltaic cell is a thin-film photovoltaic cell.

6. The device of claim 5, further comprising a ceramic capacitor electrically coupled to a string of the thin-film photovoltaic cells which include the at least one photovoltaic cell.

7. The device of claim 6, wherein the transformerless inverter comprises a transformerless buck converter.

8. The device of claim 7, wherein the transformerless buck converter comprises at least one of a synchronous buck converter or an asynchronous buck converter.

9. The device of claim 7, further comprising a controller coupled to the transformerless buck converter, the controller comprising a peak power tracker and at least one of a discontinuous conduction mode controller or a boundary conduction mode controller.

10. The device of claim 9, wherein the transformerless buck converter comprises at least one transistor, at least one diode, and at least one inductor for asynchronous operation; or at least two transistors and at least one inductor for synchronous operation.

11. The device of claim 10, wherein the at least one inductor is integrated onto a printed circuit board or at least one layer of the package.

12. The device of claim 9, wherein the transformerless inverter further comprises a transformerless boost converter electrically coupled to the controller.

13. The device of claim 7, wherein the transformerless inverter comprises a transformerless buck-boost converter.

14. A method of operating a photovoltaic device, comprising:
providing an input power from a photovoltaic cell to a transformerless DC/DC converter;
operating the transformerless DC/DC converter in at least one of a discontinuous conduction mode or a boundary conduction mode; and
providing an output power from the transformerless DC/DC converter to an unfolder.

15. The method of claim 14, wherein the transformerless DC/DC converter comprises a transformerless buck converter.

16. The method of claim 15, wherein the step of operating comprises operating the transformerless buck converter in discontinuous conduction mode.

17. The method of claim 16, wherein operating the transformerless buck converter in discontinuous conduction mode comprises ending a switching period of the transformerless buck converter after an inductor current of the transformerless buck converter reaches zero.

18. The method of claim 17, wherein the transformerless buck converter comprises at least one transistor, at least one diode, and at least two integrated inductors.

19. The method of claim 17, further comprising controlling a duty cycle of the switching period in order to shape an output of the unfolder.

20. The method of claim 15, wherein the step of operating comprises operating the transformerless buck converter in boundary conduction mode.

21. The method of claim 20, wherein operating the transformerless buck converter in boundary conduction mode comprises ending a switching period of the transformerless buck converter when a current of one of the at least two integrated inductors reaches zero.

22. The method of claim 15, wherein the transformerless DC/DC converter further comprises a transformerless boost converter.

23. The method of claim 22, wherein the transformerless buck converter and the transformerless boost converter together comprise at least two transistors controlled by a controller, and wherein the transformerless buck converter and the transformerless boost converter operate in different modes.

24. The method of claim 14, wherein the transformerless DC/DC converter further comprises a transformerless buck-boost converter.

25. The method of claim 14, wherein the photovoltaic cell, the transformerless DC/DC converter, and the unfolder comprise a photovoltaic package less than 11 mm thick.

26. A photovoltaic circuit, comprising:
at least one photovoltaic cell;
a storage capacitor electrically coupled to the at least one photovoltaic cell;
a transformerless DC/DC converter electrically coupled to the storage capacitor;
an electromagnetic interference (EMI) filter electrically coupled to the transformerless DC/DC converter;
an unfolder electrically coupled to the EMI filter; and
a controller electrically coupled to the transformerless DC/DC converter.

27. The circuit of claim 26, wherein the at least one photovoltaic cell, the storage capacitor, the transformerless DC/DC converter, the EMI filter, the unfolder, and the controller are integrated into a photovoltaic package.

28. The circuit of claim 27, wherein the photovoltaic package comprises a low-profile laminate or non-laminate package.

29. The circuit of claim 28, wherein the low-profile package is less than 11 mm thick.

30. The circuit of claim 29, wherein the low-profile package is less than 5 mm thick.

31. The circuit of claim 27, wherein the DC/DC converter comprises a buck converter.

32. The circuit of claim 31, wherein the DC/DC converter further comprises a boost converter, and wherein the DC/DC converter comprises at least two transistors.

33. The circuit of claim 27, wherein the DC/DC converter comprises a buck-boost converter.

34. The circuit of claim 31, further comprising a controller coupled to the buck converter, the controller comprising a maximum power point tracker and at least one of a discontinuous conduction mode controller or a boundary conduction mode controller.

35. The circuit of claim 34, wherein the controller partially comprises digital circuitry.

36. The circuit of claim 28, wherein the EMI filter comprises at least one inductor integrated into a printed circuit board.

37. The circuit of claim 28, wherein components of the transformerless DC/DC converter, the EMI filter, or the unfolder are integrated onto at least one of a printed circuit board, a flex circuit, a substrate, or back barrier of the package.
